(19) United States
(12) Patent Application Publication
(10) Pub. No.: US 2025/0377433 A1
(43) Pub. Date: Dec. 11, 2025

(54) ABNORMALITY DETECTION DEVICE

(71) Applicants: SUBARU CORPORATION, Tokyo (JP); TOYOTA JIDOSHA KABUSHIKI KAISHA, Aichi-ken (JP); ISUZU MOTORS LIMITED, Kanagawa (JP); HINO MOTORS, LTD., Tokyo (JP); HONDA MOTOR CO., LTD., Tokyo (JP)

(72) Inventors: Takahiro KINOSHITA, Tokyo (JP); Yoshio NISHINO, Ichinomiya-shi (JP); Yutaka HAYASHI, Nagakute-shi (JP); Kazumasa KITANOBOH, Okazaki-shi (JP)

(21) Appl. No.: 19/225,224

(22) Filed: Jun. 2, 2025

(30) Foreign Application Priority Data
Jun. 5, 2024 (JP) 2024-091833

(51) Int. Cl. G01R 35/00; G01R 15/14; G01R 19/165

(52) U.S. Cl. CPC G01R 35/00; G01R 15/146; G01R 19/16504

(57) ABSTRACT

An abnormality detection device includes: first resistance elements; a second resistance element; and a control device. The control device includes one or more processors, and one or more memories coupled to the processors. The processor is configured to execute processes including deriving a first current value of the current flowing through one or more the first resistance elements among the multiple first resistance elements, deriving a second current value of the current flowing through the second resistance element, and determining whether there is a characteristic abnormality in the first resistance element, based on a comparison result between the first current value and the second current value.

### CROSS-REFERENCE TO RELATED APPLICATIONS

The present application claims priority from Japanese Patent Application No. 2024-091833 filed on Jun. 5, 2024, the entire contents of which are hereby incorporated by reference.

### TECHNICAL FIELD The disclosure relates to an abnormality detection device.

### BACKGROUND

For example, Japanese Unexamined Patent Application Publication (JP-A) No. 2021-148511 discloses a technique for determining an abnormality in a resistance value of a shunt resistor in a current detection circuit. In this Patent Literature 1, shunt resistors are provided in the circuit, and among multiple current values of the shunt resistors, when there is a current value whose ratio to an average current value is greater than an abnormality threshold, it is determined that there is an abnormality in a resistance value of the shunt resistor corresponding to that current value.

### SUMMARY

An abnormality detection device includes: first resistance elements having one ends electrically coupled to one another and the other ends coupled to loads; a second resistance element having one end coupled to a power supply and the other end electrically coupled to a coupling node at which the one ends of the first resistance elements are electrically coupled to one another; and a control device. The control device includes one or more processors, and one or more memories coupled to the processors. The processor is configured to execute processes including deriving a first current value of the current flowing through one or more the first resistance elements among the multiple first resistance elements, deriving a second current value of the current flowing through the second resistance element, and determining whether there is a characteristic abnormality in the first resistance element, based on a comparison result between the first current value and the second current value.

### BRIEF DESCRIPTION OF THE DRAWINGS

FIG. 1 is a schematic diagram illustrating a configuration of a power supply system including an abnormality detection device according to an embodiment of the disclosure.

FIG. 2 is a flowchart illustrating a flow of an operation of an abnormality detector.

FIG. 3 is a flowchart illustrating a flow of an operation of an abnormality detector according to a modification in which a switch is actively controlled.

### DETAILED DESCRIPTION

When a characteristic abnormality occurs in a resistance element serving as a current sensor, control based on a current value detected by the resistance element may no longer be performed appropriately, and for example, an overcurrent may flow through a load coupled to the resistance element. Therefore, it is desired to detect a characteristic abnormality of the resistance element.

As a method for detecting a characteristic abnormality of the resistance element, for example, for each first resistance element serving as a current sensor, a resistance element for abnormality detection is coupled in series to the first resistance element, and current values of the resistance elements are compared. However, in this example, as the number of first resistance elements increases, the same number of resistance elements for abnormality detection and amplifier circuits used to derive the current values based on a voltage drop of the resistance elements may be also used as the first resistance elements. Therefore, in this example, as the number of first resistance elements increases, costs of the current sensor may increase.

Therefore, it is desirable to provide an abnormality detection device capable of appropriately detecting a characteristic abnormality of a resistance element while reducing costs.

Hereinafter, an embodiment of the disclosure will be described in detail with reference to the accompanying drawings. The specific dimensions, materials, numerical values, and the like shown in the embodiment are merely examples for facilitating the understanding of the invention, and do not limit the disclosure unless otherwise specified. In the present description and the drawings, substantially the same elements are denoted by the same reference signs, and a repeated description thereof is omitted, and elements having no direct relation with the disclosure are not illustrated.

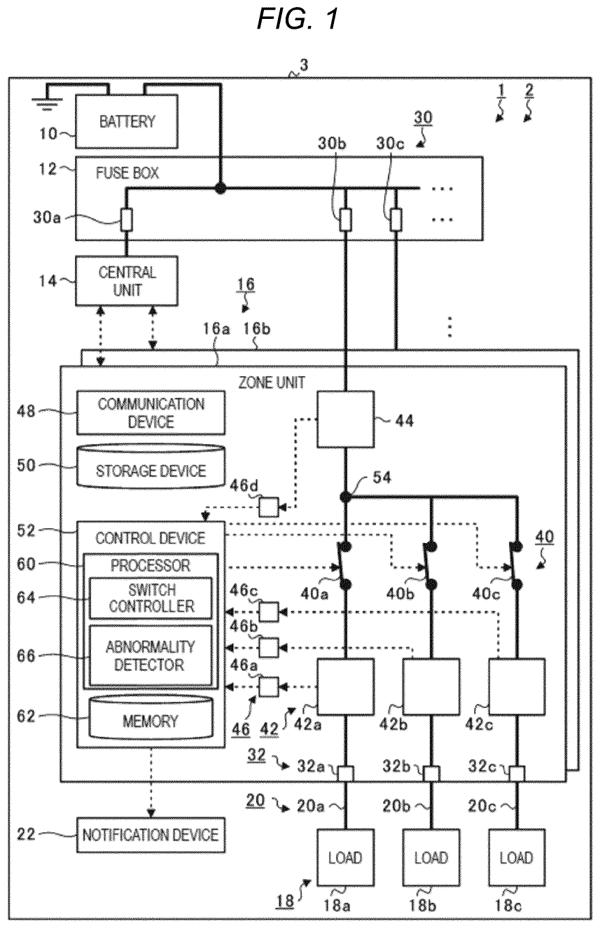

FIG. 1 is a schematic diagram illustrating a configuration of a power supply system 2 including an abnormality detection device 1 according to an embodiment of the disclosure. The abnormality detection device 1 and the power supply system 2 are applied to, for example, a vehicle 3. The vehicle 3 is, for example, an electric automobile including a motor generator as a driving source. The vehicle 3 may be a hybrid electric automobile including a motor generator and an engine as a driving source, or may be an engine vehicle including an engine as a driving source.

The power supply system 2 includes a battery 10, a fuse box 12, a central unit 14, zone units 16a and 16b, loads 18a, 18b, and 18c, downstream electric wires 20a, 20b, and 20c, and a notification device 22.

Hereinafter, for convenience of description, the zone units 16a and 16b may be collectively referred to as a zone unit 16. The loads 18a, 18b, and 18c may be collectively referred to as a load 18. The downstream electric wires 20a, 20b, and 20c may be collectively referred to as a downstream electric wire 20.

The battery 10 is, for example, a lead storage battery, and is a rechargeable secondary battery. The battery 10 serves as a power supply that supplies electric power to various auxiliary machines, electronic devices, and the like mounted on the vehicle 3.

Fuses 30a, 30b, and 30c are accommodated in the fuse box 12. Hereinafter, for convenience of description, the fuses 30a, 30b, and 30c may be collectively referred to as a fuse 30.

A first terminal of two terminals of the fuse 30a is coupled to the battery 10. A second terminal of the fuse 30a is coupled to the central unit 14. The central unit 14 is electrically coupled to the battery 10 through the fuse 30a.

A first terminal of two terminals of the fuse 30b is coupled to the battery 10. A second terminal of the fuse 30b is coupled to the zone unit 16a. A first terminal of two terminals of the fuse 30c is coupled to the battery 10. A second terminal of the fuse 30c is coupled to the zone unit 16b. The zone units 16a and 16b are electrically coupled to the battery 10 through the fuses 30b and 30c, respectively.

Although two zone units 16a and 16b are illustrated in FIG. 1, the number of zone units 16 is not limited to two, and may be one, or three or more. Although three fuses 30a, 30b, and 30c are illustrated in FIG. 1, the number of fuses 30 is not limited to three, and may be equal to or greater than the total number of central units 14 and zone units 16.

The central unit 14 is, for example, an electronic control unit (ECU) having the highest rank that collectively controls various devices and an electronic control unit (ECU) mounted on the vehicle 3. Although not illustrated, the central unit 14 includes a processor and a memory, and controls each member of the vehicle 3 by the processor executing a program. The central unit 14 is capable of establishing communication with each of the zone units 16.

The zone unit 16 is, for example, an electronic control unit (ECU) having a rank lower than the central unit 14 in the network architecture. In the present embodiment, the zone units 16 have a common configuration. In FIG. 1, for simplification of the drawing, the configuration of the zone unit 16a among the multiple zone units 16 is illustrated, and the configurations of the other zone units 16 are omitted.

The zone unit 16 includes power supply output ports 32a, 32b, and 32c. Hereinafter, the power supply output ports 32a, 32b, and 32c may be collectively referred to as a power supply output port 32. Although FIG. 1 illustrates an example in which the zone unit 16 includes three power supply output ports 32a, 32b, and 32c, the number of power supply output ports 32 is not limited to three, and may be any number greater than one, such as two or four or more.

The load 18a is electrically coupled to the power supply output port 32a of the zone unit 16a through the downstream electric wire 20a. The load 18b is electrically coupled to the power supply output port 32b of the zone unit 16a through the downstream electric wire 20b. The load 18c is electrically coupled to the power supply output port 32c of the zone unit 16a through the downstream electric wire 20c.

The load 18 may be any electric device such as an actuator. The load 18 may be any electronic device such as an electronic control unit (ECU) having a rank lower than the central unit 14 and the zone unit 16 in the network architecture. The loads 18 coupled to the zone unit 16 may be the same devices or different devices. Although not illustrated, another load 18 may be coupled to another zone unit 16 other than the zone unit 16a through another downstream electric wire 20.

The downstream electric wire 20 electrically couples a predetermined load 18 to the zone unit 16. For example, the downstream electric wire 20 may be an electric wire for electrical equipment of the vehicle 3, the electric wire having a high heat resistance temperature. The downstream electric wires 20 may be different electric wires and have different cross-sectional areas depending on the magnitude of the current used in the load 18 coupled to the downstream electric wire 20.

The notification device 22 is, for example, a warning light of an instrument panel, and is capable of notifying an occupant of the vehicle 3 of predetermined content.

In addition to the power supply output port 32, the zone unit 16 includes switches 40a, 40b, and 40c, first resistance elements 42a, 42b, and 42c, a second resistance element 44, amplifier circuits 46a, 46b, 46c, and 46d, a communication device 48, a storage device 50, and a control device 52.

Hereinafter, the switches 40a, 40b, and 40c may be collectively referred to as a switch 40. The first resistance elements 42a, 42b, and 42c may be collectively referred to as a first resistance element 42. The amplifier circuits 46a, 46b, 46c, and 46d may be collectively referred to as an amplifier circuit 46. The first resistance element 42 and the second resistance element 44 may be collectively referred to simply as a resistance element.

Although three switches 40a, 40b, and 40c are illustrated in FIG. 1, the number of switches 40 is not limited to three, and may be one, two, or four or more. Although three first resistance elements 42a, 42b, and 42c are illustrated in FIG. 1, the number of first resistance elements 42 is not limited to three, and may be any number greater than one, such as two or four or more. For example, the number of the switch 40 is the same as the number of first resistance elements 42 and the same as the number of power supply output ports 32.

The switch 40 is, for example, a semiconductor switch such as a metal oxide semiconductor field effect transistor (MOSFET). The switch 40 is capable of switching between electrical coupling and interruption between two contacts of the switch 40. As will be described later, the control device 52 can control the on and off of the switch 40.

A first contact of two contacts of the switch 40a, a first contact of two contacts of the switch 40b, and a first contact of two contacts of the switch 40c are coupled to one another.

A second contact of the two contacts of the switch 40a is coupled to a first terminal of two terminals of the first resistance element 42a. A second terminal of the two terminals of the first resistance element 42a is coupled to the power supply output port 32a. A second contact of the two contacts of the switch 40b is coupled to a first terminal of two terminals of the first resistance element 42b. A second terminal of the two terminals of the first resistance element 42b is coupled to the power supply output port 32b. A second contact of the two contacts of the switch 40c is coupled to a first terminal of two terminals of the first resistance element 42c. A second terminal of the two terminals of the first resistance element 42c is coupled to the power supply output port 32c.

As described above, the switches 40 are associated with the first resistance elements 42 in a one-to-one correspondence and are coupled in series to the first resistance elements 42, respectively.

In the zone unit 16, the first contact of the switch 40a, the first contact of the switch 40b, and the first contact of the switch 40c are coupled to one another, and a coupling node 54 is provided. Thus, one ends of the first resistance elements 42 are electrically coupled to one another at the coupling node 54 via the switch 40. In other words, one ends of the first resistance elements 42 are electrically coupled to one another via the switch 40, and the coupling node 54 is provided.

The load 18 is coupled to the other end of each of the first resistance elements 42 via the power supply output port 32 and the downstream electric wire 20.

The first resistance element 42 is, for example, a shunt resistor. The first resistance element 42 serves as a current sensor that detects the current flowing through the first resistance element 42, in other words, the current flowing through the switch 40, the downstream electric wire 20, and the load 18 coupled to the first resistance element 42. The first resistance element 42 detects the current using a voltage drop based on a resistance value of the first resistance element 42. The voltage drop across the first resistance element 42 refers to the voltage across the first resistance element 42.

A first terminal of two terminals of the second resistance element 44 is electrically coupled to the battery 10 serving as a power supply via the fuse 30b. A second terminal of the two terminals of the second resistance element 44 is electrically coupled to the coupling node 54.

The second resistance element 44 is, for example, a shunt resistor. The second resistance element 44 serves as a current sensor that detects the current flowing through the second resistance element 44. The second resistance element 44 detects the current using a voltage drop based on a resistance value of the second resistance element 44. The voltage drop across the second resistance element 44 refers to the voltage across the second resistance element 44.

Hereinafter, a current value of the current flowing through the first resistance element 42, in other words, the current value detected by the first resistance element 42 may be referred to as a first current value. A current value of the current flowing through the second resistance element 44, in other words, the current value detected by the second resistance element 44 may be referred to as a second current value.

The resistance value of the first resistance element 42 and the resistance value of the second resistance element 44 are set to relatively small values so as not to hinder the supply of current to the downstream load 18 as much as possible. Therefore, the amount of change in the voltage drop corresponding to the current flowing through the first resistance element 42 and the second resistance element 44 is very small.

The amplifier circuit 46 amplifies the voltage drop of the resistance element to a value that can be processed by the control device 52 and outputs the amplified voltage drop to the control device 52. For example, the amplifier circuit 46a amplifies the voltage drop of the first resistance element 42a and outputs the amplified voltage drop to the control device 52. The amplifier circuit 46b amplifies the voltage drop of the first resistance element 42b and outputs the amplified voltage drop to the control device 52. The amplifier circuit 46c amplifies the voltage drop of the first resistance element 42c and outputs the amplified voltage drop to the control device 52. The amplifier circuit 46d amplifies the voltage drop of the second resistance element 44 and outputs the amplified voltage drop to the control device 52.

A resistance value of the resistance element is set in consideration of a range of a current

value desired to be detected by the resistance element and a range of a voltage value that can be input to the control device 52. The resistance value of the resistance element may be set to a predetermined value within a range of several mΩ to several hundred mΩ, for example.

As an example, it is assumed that the range of the current value desired to be detected by the resistance element is 0 A to 300 A, and the range of voltage value that can be input to the control device 52 is 0 V to 5 V. In this example, the resistance value of the resistance element may be set to 16.7 mΩ (5 V/300 A=16.7 mΩ). For example, when the range of the current value desired to be detected by the resistance element is 0 A to 900 A and the range of the voltage value that can be input to the control device 52 is 0 V to 5 V, the resistance value of the resistance element may be set to 5.6 mΩ (5 V/900 A≈5.6 mΩ). Based on these, the resistance value of the resistance element is set to a smaller value as a maximum value of the range of the current value desired to be detected by the resistance element increases.

Hereinafter, for convenience of description, the range of the current value desired to be detected may be referred to as a detection range, and the maximum value of the range of the current value desired to be detected may be referred to as a maximum detection value.

In the zone unit 16, for example, the detection range of the first resistance element 42 is set to be the same for the first resistance elements 42. That is, the resistance value of the first resistance element 42 is set to be substantially the same for each of the first resistance elements 42.

In the zone unit 16, the use of the power supply output port 32 may be classified, for example, as for high power or low power, according to the classification of the magnitude of the current supplied to the load 18 coupled downstream of the power supply output port 32. In this example, the setting of the detection range of the first resistance element 42 and the setting of the resistance value of the first resistance element 42 may be different for the first resistance elements 42 according to the use or the power classification of the power supply output port 32. For example, the resistance value of the first resistance element 42 coupled to the power supply output port 32 for high power may be set to a value smaller than the resistance value of the first resistance element 42 coupled to the power supply output port 32 for low power.

The second resistance element 44 is electrically coupled to each of the first resistance elements 42 via the coupling node 54. Therefore, the current flowing through the second resistance element 44 is shunted to each of the first resistance elements 42 via the coupling node 54.

A current greater than or equal to the current value of the current flowing through each of the first resistance elements 42 flows through the second resistance element 44. Therefore, the resistance value of the second resistance element 44 is set to a value at least equal to or less than the resistance value of each of the first resistance elements 42.

For example, the resistance value of the second resistance element 44 may be set to satisfy the following Formula (1). In Formula (1), Xa, Xb, and Xc represent the resistance values of the first resistance elements 42a, 42b, and 42c, respectively, and Y represents the resistance value of the second resistance element 44. 1/Y=1/Xa+1/Xb+1/Xc . . . (1)

That is, the resistance value of the second resistance element 44 may be set such that the total value (1/Xa+1/Xb+1/Xc) of reciprocals of the resistance values of the first resistance elements 42 is the reciprocal (1/Y) of the resistance value of the second resistance element 44.

For example, it is assumed that the maximum detection values of the first resistance elements 42a, 42b, and 42c are 300 A. Since the current flowing through the second resistance element 44 is shunted to each of the first resistance elements 42, the maximum detection value of the second resistance element 44 is 900 A, which is the sum of the maximum detection values of the first resistance elements 42 according to the number of first resistance elements 42. It is also assumed that a maximum value of the range of the voltage value that can be input to the control device 52 is 5 V.

In this example, the maximum detection value of the first resistance element 42a is equal to a value obtained by dividing 5 V by the resistance value Xa of the first resistance element 42a (300 A=5 V/Xa). The maximum detection value of the first resistance element 42b is equal to a value obtained by dividing 5 V by the resistance value Xb of the first resistance element 42b (300 A=5 V/Xb). The maximum detection value of the first resistance element 42c is equal to a value obtained by dividing 5 V by the resistance value Xc of the first resistance element 42c (300 A=5 V/Xc). The maximum detection value of the second resistance element 44 is equal to a value obtained by dividing 5 V by the resistance value Y of the second resistance element 44 (900 A=5 V/Y). The maximum detection value of the second resistance element 44 is equal to the sum of the maximum detection value of the first resistance element 42a, the maximum detection value of the first resistance element 42b, and the maximum detection value of the first resistance element 42c (900 A=300 A+300 A+300 A, that is, 5 V/Y=5 V/Xa+5 V/Xb+5 V/Xc). Then, by dividing both sides by 5 V, the above Formula (1) is derived. In this case, since the maximum detection values of the first resistance elements 42a, 42b, and 42c are all 300 A, when the resistance values Xa, Xb, and Xc of the first resistance elements 42a, 42b, and 42c are the same (Xa=Xb=Xc), the resistance value Y of the second resistance element 44 is one third the resistance value Xa of the first resistance element 42a (Y=Xa/3). For example, when the resistance values Xa, Xb, and Xc are each 16.7 mΩ (5 V/300 A=16.7 mΩ), the resistance value Y may be 5.6 mΩ (16.7 mΩ/3=5.6 mΩ).

In the power supply system 2, by setting the resistance value of the second resistance element 44 based on the above Formula (1), the first current value of the first resistance element 42 can be obtained with appropriate resolution, and the second current value of the second resistance element 44 can be obtained with appropriate resolution.

The communication device 48 includes a communication network such as a control area network (CAN) with a communication device of another electronic control unit mounted on the vehicle 3. The zone unit 16 can communicate with the central unit 14 through the communication device 48.

The storage device 50 includes an electrically writable nonvolatile storage element. The storage device 50 stores various data such as data indicating the characteristics of the downstream electric wire 20.

The control device 52 is, for example, a microcomputer, but is not limited to a microcomputer, and may be a microcomputer-less structure such as an application specific integrated circuit (ASIC). The control device 52 includes one or more processors 60 and one or more memories 62 coupled to the processors 60. The memory 62 includes a ROM in which a program and the like are stored and a RAM as a work area. The processor 60 controls the zone unit 16 in cooperation with a program in the memory 62. For example, the processor 60 serves as a switch controller 64 and an abnormality detector 66 by executing a program.

The switch controller 64 controls the on and off of the switches 40a, 40b, and 40c. For example, when the switch controller 64 receives an instruction to turn on and off the switches 40 from the central unit 14, the switch controller 64 turns on and off the switches 40 according to the instruction.

The switch controller 64 can cause the switch 40 to serve as a fuse. For example, the switch controller 64 obtains the voltage drop of the first resistance element 42 through the amplifier circuit 46. The switch controller 64 derives the current value of the current flowing through the first resistance element 42 based on the obtained voltage drop. The switch controller 64 estimates the temperature of the switch 40 corresponding to the first resistance element 42, based on the derived current value. When the estimated temperature exceeds a predetermined temperature, the switch 40 is turned off to electrically interrupt the load 18 downstream of the switch 40.

When the switch controller 64 controls the on and off of each of the switches 40, the switch controller 64 may store in the memory 62 an on state or off state of each of the switches 40 after the control.

When the first resistance element 42 deteriorates over time and rust or the like occurs, the resistance value of the first resistance element 42 may deviate from an appropriate value. In addition, for example, in the manufacturing process of the zone unit 16, a failure may occur in which the first resistance element 42 having a resistance value different from the appropriate resistance value is attached. In this way, when the resistance value of the first resistance element 42 deviates from an appropriate range, the current value derived based on the voltage drop of the first resistance element 42 deviates from the appropriate value, and for example, the switch 40 may not be properly turned off.

The abnormality detector 66 determines whether the first resistance elements 42 have a characteristic abnormality. The characteristic abnormality includes an abnormality in the resistance value of the first resistance element 42.

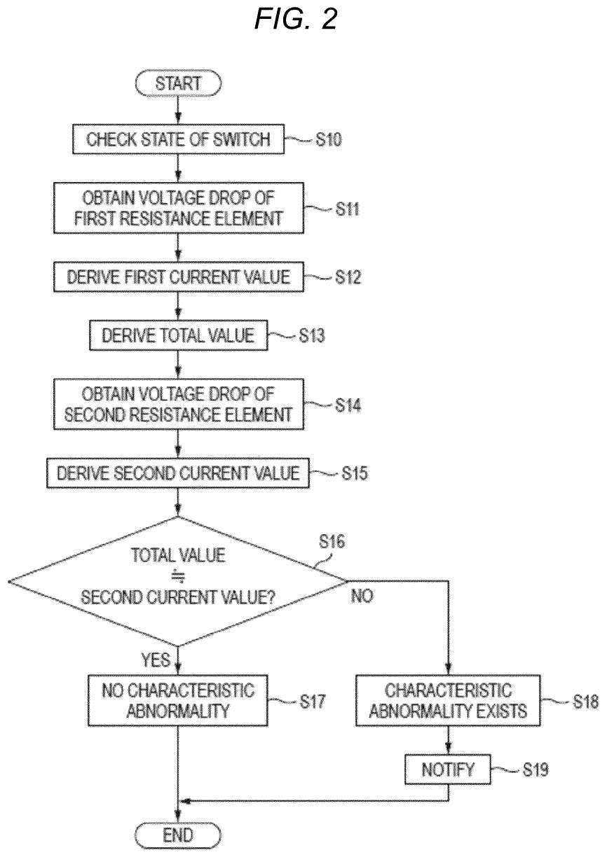

FIG. 2 is a flowchart illustrating a flow of an operation of an abnormality detector 66. The abnormality detector 66 repeatedly executes a series of processes illustrated in FIG. 2 every time a predetermined interrupt timing occurs, which occurs at a predetermined cycle, such as every several hundred ms.

When a predetermined interrupt timing occurs, the abnormality detector 66 checks the state of the switch 40 (S10). For example, the abnormality detector 66 may check the state of the switch 40 by reading out the present state of the switch 40 stored in the memory 62.

The abnormality detector 66 specifies one or more first resistance elements 42 whose switch 40 is in the on state among the multiple first resistance elements 42, and obtains the voltage drop of the specified first resistance element 42 via the amplifier circuit 46 (S11).

The abnormality detector 66 derives the first current value of the first resistance element 42 specified in step S11 based on the voltage drop obtained in step S11 (S12).

The abnormality detector 66 derives a total value of the first current values of the one or more first resistance elements 42 (first resistance elements 42 specified in step S11) corresponding to the switches 40 that are in the on state (S13).

For example, when the switches 40a, 40b, and 40c are in the on state, the abnormality detector 66 adds the first current value of the first resistance element 42a, the first current value of the first resistance element 42b, and the first current value of the first resistance element 42c to derive a total value. For example, when the switches 40a and 40b are in the on state and the switch 40c is in the off state, the abnormality detector 66 adds the first current value of the first resistance element 42a and the first current value of the first resistance element 42b to derive a total value. When there is one switch 40 in the on state, the first current value of one first resistance element 42 corresponding to the one switch 40 in the on state is set as a total value.

The abnormality detector 66 obtains the voltage drop of the second resistance element 44 via the amplifier circuit 46 (S14).

The abnormality detector 66 derives the second current value of the second resistance element 44, based on the voltage drop obtained in step S14 (S15).

The abnormality detector 66 determines whether the total value derived in step S13 substantially matches the second current value derived in step S15 (S16). In other words, the abnormality detector 66 determines whether the total value derived in step S13 falls within a predetermined range including the second current value derived in step S15. Here, the predetermined range is set to such an extent that the total value and the second current value can be regarded as matching within an acceptable error range. That is, the predetermined range including the second current value is a range expanded by the amount of error with the second current value as a reference.

When the abnormality detector 66 determines that the total value matches the second current value, in other words, when the abnormality detector 66 determines that the total value falls within the predetermined range including the second current value (YES in S16), the abnormality detector 66 determines that the first resistance element 42 whose corresponding switch 40 is in the on state among the multiple first resistance elements 42 has no characteristic abnormality (S17), and ends the series of processes.

On the other hand, when the abnormality detector 66 determines that the total value does not match the second current value, in other words, when the abnormality detector 66 determines that the total value is out of the predetermined range including the second current value (NO in S16), the abnormality detector 66 determines that the first resistance element 42 corresponding to the switch 40 in the ON state among the multiple first resistance elements 42 has a characteristic abnormality (S18).

As described above, the resistance value of the first resistance element 42 is set to a relatively small value so as not to hinder the supply of current to the downstream load 18 as much as possible. Therefore, even when a characteristic abnormality occurs in the first resistance element 42 and the resistance value of the first resistance element 42 changes, the resistance value after the change is assumed to be very small with respect to the load 18. Therefore, even when the characteristic abnormality occurs in the first resistance element 42, the current value of the actual current supplied to the load 18 is almost the same as that before the characteristic abnormality occurs in the first resistance element 42, and there is almost no influence on the actual current supplied to the load 18.

However, the control device 52 causes the amplifier circuit 46 to amplify the voltage drop based on a small resistance value of the first resistance element 42 to derive the current value. Therefore, when the resistance value of the first resistance element 42 changes, the calculated current value changes. In this case, the total value of the calculated first current values of the first resistance elements 42 also changes.

Therefore, when the resistance value of the first resistance element 42 changes, the total value of the actual current values of the first resistance elements 42 would be equal to the actual current value of the second resistance element 44, but the total value of the calculated first current values of the first resistance elements 42 does not substantially match the calculated second current value of the second resistance element 44. The abnormality detector 66 determines the characteristic abnormality of the first resistance element 42 when the calculated current values do not match.

When there are multiple switches 40 in the on state, the abnormality detector 66 may determine that one or more of the first resistance elements 42 corresponding to one or more of the switches 40 in the on state has a characteristic abnormality. In this case, which of the first resistance elements 42 corresponding to the switches 40 in the on state has the characteristic abnormality, is not specified. However, since the first resistance elements 42 are soldered to a substrate in the zone unit 16, when the characteristic abnormality occurs in any one of the first resistance elements 42, repair for replacing the zone unit 16 will be performed. Therefore, when it is possible to specify that one of the first resistance elements 42 has a characteristic abnormality, it is not necessary to specify which of the first resistance elements 42 has a characteristic abnormality.

After determining that there is the characteristic abnormality, the abnormality detector 66 causes the notification device 22 to notify that there is the characteristic abnormality in the first resistance element 42 (S19), and ends the series of processes. The notification device 22 is not limited to notify that there is a characteristic abnormality in the first resistance element 42, but may also notify that there is an abnormality in the zone unit 16 including the first resistance element 42 that is determined to have a characteristic abnormality.

When an occupant of the vehicle 3 confirms the characteristic abnormality of the first resistance element 42 through the notification device 22, the vehicle 3 can be repaired. In the repair of the vehicle 3, the zone unit 16 including the first resistance element 42 having the characteristic abnormality is replaced.

Either of the processing of obtaining the voltage drop of the first resistance element 42 and deriving the first current value and the processing of obtaining the voltage drop of the second resistance element 44 and deriving the second current value may be performed first, or may be performed in parallel.

The disclosure is not limited to an aspect in which the voltage drop of the first resistance element 42 corresponding to the switch 40 in the on state is obtained and the voltage drop of the first resistance element 42 corresponding to the switch 40 in the off state is not obtained. For example, the abnormality detector 66 may obtain the voltage drops of all the first resistance elements 42 regardless of the state of the switch 40. In this example, the abnormality detector 66 may derive a total value by deriving a current value for each of the obtained voltage drops. When the switch 40 is in the off state, there is substantially no voltage drop, and the first current value of the first resistance element 42 corresponding to the switch 40 in the off state would be zero. However, for example, when it is determined that the first current value of the first resistance element 42 corresponding to the switch 40 in the off state does not become zero and the total value of the first current values does not substantially match the second current value, the abnormality detector 66 may determine that there is a characteristic abnormality in the first resistance element 42.

As described above, the abnormality detection device 1 of the present embodiment includes the first resistance elements 42 having one ends electrically coupled to one another and the other ends coupled to loads, respectively, the second resistance element 44 having one end coupled to a power supply and the other end electrically coupled to a coupling node 54 at which the one ends of the first resistance elements 42 are electrically coupled to one another, and the control device 52. In the abnormality detection device 1 of the present embodiment, the abnormality detector 66 of the control device 52 derives a first current value of the current flowing through one or more of the first resistance elements 42. The abnormality detector 66 derives a second current value of the current flowing through the second resistance element 44. The abnormality detector 66 determines whether there is a characteristic abnormality in the first resistance elements 42, based on a comparison result between the first current value and the second current value.

For example, in the abnormality detection device 1 of the present embodiment, the abnormality detector 66 derives the first current value of the current flowing through one or more first resistance elements 42 among the multiple first resistance elements 42, the corresponding switch 40 of which is in the on state. The abnormality detector 66 derives a second current value of the current flowing through the second resistance element 44. When a total value of the first current values of the first resistance elements 42 whose corresponding switches 40 are in the on state is out of the predetermined range including the second current value, the abnormality detector 66 determines that there is the characteristic abnormality in the first resistance element 42 whose corresponding switch 40 is in the on state among the multiple first resistance elements 42.

Accordingly, in the abnormality detection device 1 of the present embodiment, even when multiple first resistance elements 42 are provided, it is possible to determine the characteristic abnormality of the first resistance element 42 by providing one second resistance element 44 for abnormality detection. Therefore, in the abnormality detection device 1 of the present embodiment, for example, compared with an aspect in which a resistance element for abnormality detection is provided for each of the first resistance elements 42, an increase in costs for current sensors can be prevented even when the number of first resistance elements 42 is increased.

According to the abnormality detection device 1 of the present embodiment, it is possible to appropriately detect the characteristic abnormality of the resistance element while reducing the costs.

In the above embodiment, the switches 40 are provided in one-to-one correspondence with the first resistance elements 42. However, the switches 40 may be omitted, and the first resistance elements 42 may be directly electrically coupled to the second resistance element 44.

In this aspect, the abnormality detector 66 derives first current values of the current flowing through the first resistance elements 42. The abnormality detector 66 derives a second current value of the current flowing through the second resistance element 44. When the abnormality detector 66 determines that a total value of the first current values of the first resistance elements 42 is out of a predetermined range including the second current value, the abnormality detector 66 may determine that one or more of the multiple first resistance elements 42 has the characteristic abnormality.

With such a configuration, even when the number of first resistance elements 42 is increased, it is possible to prevent the increase in the costs for the current sensors, and it is possible to appropriately detect the characteristic abnormality of the resistance element while reducing the costs.

In the above embodiment, when determining whether the first resistance element 42 has the characteristic abnormality, on and off states of the switches 40 are different among the multiple switches 40. This is because the load 18 that are to be supplied with electric power is changed among the multiple loads 18 depending on states or situations of the vehicle 3.

However, the abnormality detector 66 may actively control the on and off of the switch 40 to determine the characteristic abnormality of the first resistance element 42 under a specific condition. The specific condition is when it is assumed that there will be little effect even when electric power is supplied to or cut off from the loads 18 coupled to the zone unit 16. For example, the specific condition may be a predetermined inspection time such as vehicle inspection or inspection of the vehicle 3 when the vehicle 3 is shipped from the factory.

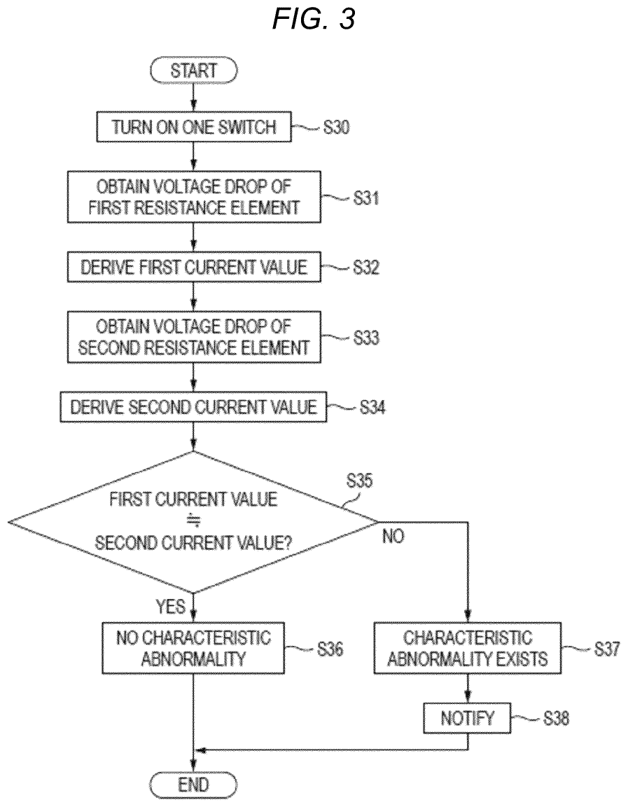

FIG. 3 is a flowchart illustrating a flow of an operation of an abnormality detector 66 according to a modification in which switches 40 are actively controlled. The abnormality detector 66 in this modification executes a series of processes in FIG. 3 when the above specific condition is satisfied.

First, the abnormality detector 66 turns on one of the switches 40 corresponding to the first resistance element 42 to be inspected for a characteristic abnormality among the multiple switches 40, and turns off the other switches 40 (S30).

The abnormality detector 66 obtains a voltage drop of the first resistance element 42 corresponding to the switch 40 in the on state via the amplifier circuit 46 (S31).

The abnormality detector 66 derives a first current value of the first resistance element 42 corresponding to the switch 40 in the on state, based on the voltage drop obtained in step S31 (S32).

The abnormality detector 66 obtains a voltage drop of the second resistance element 44 via the amplifier circuit 46 (S33).

The abnormality detector 66 derives a second current value of the second resistance element 44, based on the voltage drop obtained in step S33 (S34).

The abnormality detector 66 determines whether the first current value derived in step S32 substantially matches the second current value derived in step S34 (S35). In other words, the abnormality detector 66 determines whether the first current value derived in step S32 falls within a predetermined range including the second current value derived in step S34. Here, the predetermined range is set to such an extent that the first current value and the second current value can be regarded as matching within an acceptable error range. That is, the predetermined range including the second current value is a range expanded by the amount of error with the second current value as a reference.

When the abnormality detector 66 determines the first current value matches the second current value, in other words, when the abnormality detector 66 determines that the first current value falls within the predetermined range including the second current value (YES in S35), the abnormality detector 66 determines that there is no characteristic abnormality in the first resistance element 42 corresponding to the switch 40 in the on state (S36), and ends the series of the processes. The abnormality detector 66 may return to step S30, change the switch 40 to be turned on, and perform the processes from step S31 on again.

On the other hand, when the abnormality detector 66 determines that the first current value does not match the second current value, in other words, when the abnormality detector 66 determines that the first current value is out of the predetermined range including the second current value (NO in S35), the abnormality detector 66 determines that there is a characteristic abnormality in the first resistance element 42 corresponding to the switch 40 in the on state (S37).

After determining that there is the characteristic abnormality, the abnormality detector 66 causes the notification device 22 to notify that there is the characteristic abnormality in the first resistance element 42 corresponding to the switch 40 in the on state (S38), and ends the series of the processes. The abnormality detector 66 may return to step S30, change the switch 40 to be turned on, and perform the processes from step S31 on again.

As described above, the abnormality detector 66 of the abnormality detection device 1 according to the modification turns on one of the switches 40. The abnormality detector 66 derives the first current value of the current flowing through the first resistance element 42 corresponding to the switch 40 in the on state among the multiple first resistance elements 42. The abnormality detector 66 derives the second current value of the current flowing through the second resistance element 44. When the abnormality detector 66 determines that the first current value of the first resistance element 42 corresponding to the switch 40 in the on state is out of the predetermined range including the second current value, the abnormality detector 66 determines that there is the characteristic abnormality in the first resistance element 42 corresponding to the switch 40 in the on state.

Accordingly, in this modification as well, even when the number of first resistance elements 42 is increased, it is possible to prevent the increase in the costs for the current sensors, and it is possible to appropriately detect the characteristic abnormality of the resistance element while reducing the costs.

In this modification, it is possible to specify which of the first resistance elements 42 has a characteristic abnormality.

Although the embodiment of the disclosure have been described above with reference to the accompanying drawings, the disclosure is not limited to the embodiment. It is apparent to those skilled in the art that various modifications and alterations can be conceived within the claims, and it is understood that the modifications and alterations fall within the technical scope of the disclosure.

The processes described in the present description may not be performed in time series in the order described in the flowchart, and may include processes in parallel or in a subroutine.

In order to solve the above problem, an abnormality detection device according to one embodiment of the disclosure includes:
first resistance elements having one ends electrically coupled to one another and the other ends coupled to loads;
a second resistance element having one end coupled to a power supply and the other end electrically coupled to a coupling node at which the one ends of the first resistance elements are electrically coupled to one another; and
a control device, in which
the control device includes one or more processors, and one or more memories coupled to the processors, and
the processor is configured to execute processes including
   deriving a first current value of the current flowing through one or more of the first resistance elements among the multiple first resistance elements,
   deriving a second current value of the current flowing through the second resistance element, and
   determining whether there is a characteristic abnormality in the first resistance element, based on a comparison result between the first current value and the second current value.

According to the disclosure, it is possible to appropriately detect a characteristic abnormality of a resistance element while reducing costs.

1. An abnormality detection device comprising:
first resistance elements having one ends electrically coupled to one another and the other ends coupled to loads;
a second resistance element having one end coupled to a power supply and the other end electrically coupled to a coupling node at which the one ends of the first resistance elements are electrically coupled to one another; and
a control device, wherein
the control device includes one or more processors, and one or more memories coupled to the processors, and
the processor is configured to execute processes including
deriving a first current value of the current flowing through one or more the first resistance elements among the multiple first resistance elements,
deriving a second current value of the current flowing through the second resistance element, and
determining whether there is a characteristic abnormality in the first resistance element, based on a comparison result between the first current value and the second current value.

2. The abnormality detection device according to claim 1, wherein
the processor is configured to execute processes including
deriving the first current value of the current flowing through each of the first resistance elements,
deriving the second current value of the current flowing through the second resistance element, and
determining that there is the characteristic abnormality in one or more of the first resistance elements when it is determined that a total value of the first current values of the first resistance elements is out of a predetermined range including the second current value.

3. The abnormality detection device according to claim 1, further comprising:
switches, wherein
the switches are associated with the first resistance elements in a one-to-one correspondence and are coupled in series to the first resistance elements, respectively, and
the processor is configured to execute processes including
deriving the first current value of the current flowing through one or more first resistance elements whose corresponding switch is in an on state among the multiple first resistance elements,
deriving the second current value of the current flowing through the second resistance element, and
determining that there is the characteristic abnormality in the first resistance element corresponding to the switch in the on state among the multiple first resistance elements when it is determined that a total value of the first current values of the first resistance elements corresponding to the switches in the on state is out of a predetermined range including the second current value.

4. The abnormality detection device according to claim 1, further comprising:
switches, wherein
the switches are associated with the first resistance elements in a one-to-one correspondence and are coupled in series to the first resistance elements, respectively, and
the processor is configured to execute processes including
turning on one of the switches,
deriving the first current value of the current flowing through the first resistance element corresponding to the switch in the on state among the multiple first resistance elements,
deriving the second current value of the current flowing through the second resistance element, and
determining that there is the characteristic abnormality in the first resistance element corresponding to the switch in the on state when it is determined that the first current value of the first resistance element corresponding to the switch in the on state is out of a predetermined range including the second current value.

5. The abnormality detection device according to claim 1, wherein
a resistance value of the second resistance element is set such that a total value of reciprocals of resistance values of the first resistance elements is a reciprocal of the resistance value of the second resistance element.
